(19) United States
(12) Patent Application Publication
(10) Pub. No.: US 2026/0173727 A1
(43) Pub. Date: Jun. 18, 2026

(54) DISPLAY APPARATUS

(71) Applicant: LG Display Co., Ltd., Seoul (KR)

(72) Inventors: Jihyang YOON, Ulsan (KR); YunHo KOOK, Goyang-si (KR); Jonghan PARK, Seoul (KR); Seungpyo HONG, Paju-si (KR)

(73) Assignee: LG Display Co., Ltd., Seoul (KR)

(21) Appl. No.: 19/370,232

(22) Filed: Oct. 27, 2025

(30) Foreign Application Priority Data
Dec. 16, 2024 (KR) 10-2024-0186997

(51) Int. Cl. H10K 59/80; H10K 59/122

(52) U.S. Cl. CPC H10K 59/873; H10K 59/122; H10K 59/80515; H10K 59/80518

(57) ABSTRACT

A display apparatus is disclosed and includes a substrate including a plurality of sub pixels, an over coating layer disposed on the substrate, a first electrode disposed on each of the plurality of sub pixels, and a bank. The over coating layer including a base portion and a protrusion which protrudes from the base portion and having an inclined side surface. The first electrode covering the base portion and a part of the protrusion. The bank having an inclined side surface disposed on the first electrode and the protrusion. The bank does not cover a part of the first electrode. The bank includes a plurality of first side surfaces and a plurality of second side surfaces having an average inclination angle smaller than that of the first side surfaces.

### CROSS-REFERENCE TO RELATED APPLICATIONS

This application claims the priority of Korean Patent Application No.10-2024-0186997 filed on December 16, 2024, in the Korean Intellectual Property Office, the disclosure of which is incorporated herein by reference.

### BACKGROUND

### TECHNICAL FIELD

The present disclosure relates to a display apparatus, and more particularly, to a display apparatus which may minimize a defect that an organic encapsulation layer is not applied above a light emitting diode.

### DESCRIPTION OF THE RELATED ART

Currently, as it enters a full-scale information era, a field of a display apparatus which visually expresses electrical information signals has been rapidly developed and studies are continued to improve performances of various display apparatuses such as a thin-thickness, a light weight, and low power consumption.

Among various display apparatuses, an organic light emitting display apparatus is a self-emitting display apparatus so that a separate light source is not necessary, which is different from the liquid crystal display apparatus. Therefore, the organic light emitting display apparatus may be manufactured to have a light weight and a small thickness. Further, since the display apparatus is driven at a low voltage so that it is advantageous not only in terms of power consumption, but also in terms of color implementation, a response speed, a viewing angle, and a contrast ratio (CR). Therefore, it is expected to be utilized in various fields.

### BRIEF SUMMARY

The disclosed display apparatus uses a bank structure with multiple inclination angles and trench formations to improve encapsulation coverage over OLED pixels. By introducing first side surfaces with a steeper angle and second side surfaces as trenches with a shallower angle, the design creates narrow elongated capillary channels that guide the organic encapsulation material from the edges toward the center of the pixel. This reduces the problem where encapsulation layers do not fully cover the area above the LEDs, improving planarization, resistance to moisture, and long term device reliability.

The design also allows flexible trench placement along either the sides or vertices of polygonal sub pixels, enabling optimized flow patterns based on pixel geometry. The inclined side surfaces of the anode not only assist the flow of the encapsulation material but also act as reflective surfaces, increasing light extraction efficiency. This structure therefore addresses both optical performance and structural reliability requirements in OLED displays.

In addition, the approach is compatible with encapsulation structures that alternate organic and inorganic layers, providing improved protection against moisture and oxygen while supporting scalability for large scale manufacturing. Overall, the described structure leads to improved manufacturing yield, longer device lifetime, and enhanced display performance through a relatively simple modification of the bank and encapsulation layers.

Various embodiments of the present disclosure provide a display apparatus which minimizes a non-application defect that the organic encapsulation layer is not completely filled in an upper portion of the light emitting diode to improve the reliability of the display apparatus.

Various embodiments of the present disclosure provide a process-optimized display apparatus which improves a production yield by minimizing a non-application defect of an organic encapsulation layer to save a production energy.

Technical benefits of the present disclosure are not limited to the above-mentioned benefits , and other benefits, which are not mentioned above, can be clearly understood by those skilled in the art from the following descriptions.

According to an aspect of the present disclosure, a display apparatus includes a substrate including a plurality of sub pixels, an over coating layer which is disposed on the substrate and includes a base portion and a protrusion which protrudes from the base portion and has an inclined side surface, a first electrode which is disposed so as to correspond to each of the plurality of sub pixels and cover the base portion and a part of the protrusion, and a bank which has an inclined side surface on the first electrode and the protrusion and exposes a part of the first electrode. The bank includes a plurality of first side surfaces and a plurality of second side surfaces having an average inclination angle smaller than that of the first side surfaces.

According to another aspect of the present disclosure, a display apparatus includes a substrate, an over coating layer which is disposed on the substrate and includes a base portion and a protrusion which protrudes from the base portion and has an inclined side surface, a plurality of first electrodes disposed to cover the base portion and a part of the protruding portion, and a bank which is disposed so as to expose a part of the plurality of first electrodes on the plurality of first electrodes and the protrusion. The bank includes a top surface which is a flat surface and a side surface which is an inclined area between the ends which expose and encloses the first electrode and a plurality of trenches may be disposed on a side surface of the bank.

Other detailed matters of the exemplary embodiments are included in the detailed description and the drawings.

According to the present disclosure, a non-application defect of the organic encapsulation layer which is caused by a step of a center portion and a peripheral portion of the light emitting diode in which an anode is disposed on an inclined side surface may be minimized.

According to the present disclosure, a plurality of trenches is disposed on a side surface of a bank to induce the organic encapsulation layer to move from the peripheral portion of the light emitting diode with a step to the center portion of the light emitting diode.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display apparatus according to an exemplary embodiment of the present disclosure;

FIG. 2 is an enlarged plan view of one sub pixel of a display apparatus according to an exemplary embodiment of the present disclosure;

FIG. 3 is a cross-sectional view of a display apparatus taken along III-III′ of FIG. 2;

FIG. 4 is a cross-sectional view of a display apparatus taken along IV-IV′ of FIG. 2;

FIG. 5 is a cross-sectional view of a display apparatus taken along V-V′ of FIG. 2;

FIG. 6 is a cross-sectional view for comparing shapes of a first side surface and a second side surface of a bank of a display apparatus according to an exemplary embodiment of the present disclosure;

FIG. 7 is a cross-sectional view of a display apparatus taken along VII-VII′ of FIG. 1; and

FIG. 8 is an enlarged plan view of one sub pixel of a display apparatus according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including,’ ‘having,’ ‘consist of’ used herein are generally intended to allow other components to be added unless the terms are used with the term ‘only.’ Any references to singular may include plural unless expressly stated otherwise.

Components are interpreted to include an ordinary error range even if not expressly stated.

When the position relation between two parts is described using the terms such as ‘on,’ ‘above,’ ‘below,’ ‘next,’ one or more parts may be positioned between the two parts unless the terms are used with the term ‘immediately’ or ‘directly.’

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

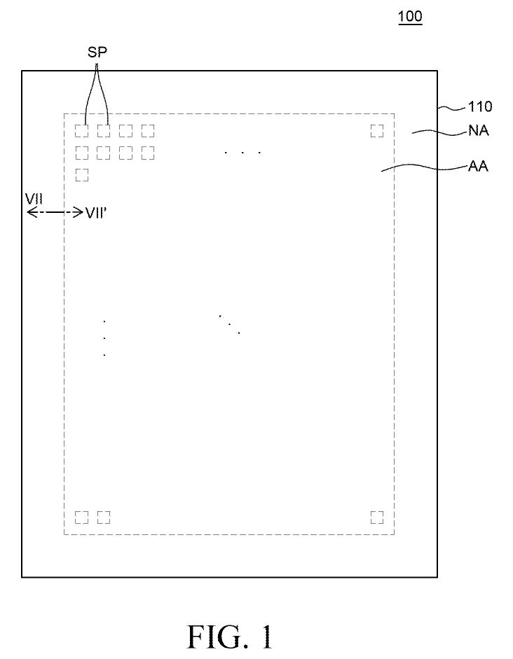

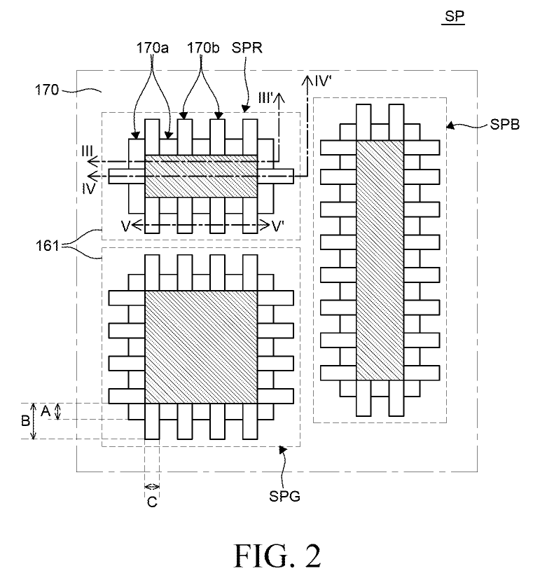

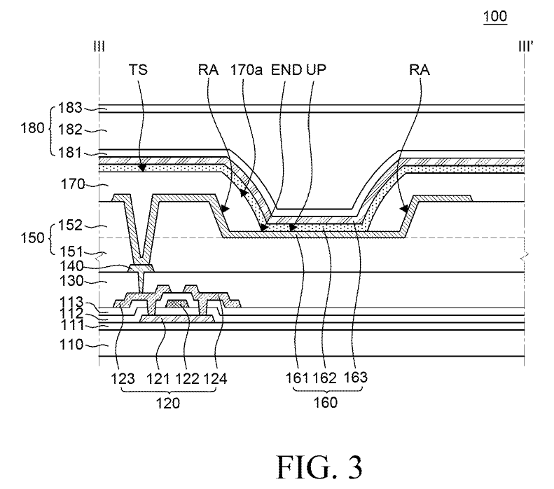

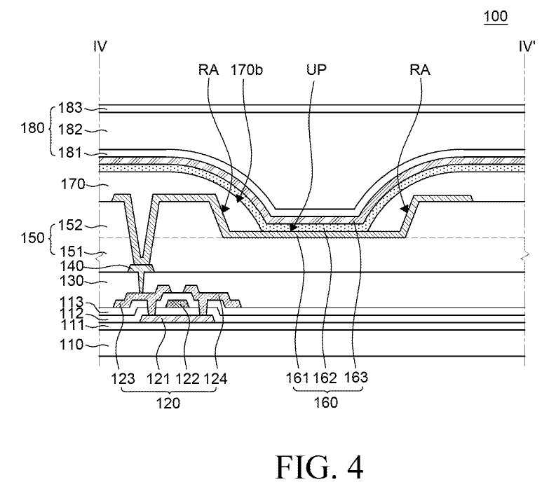

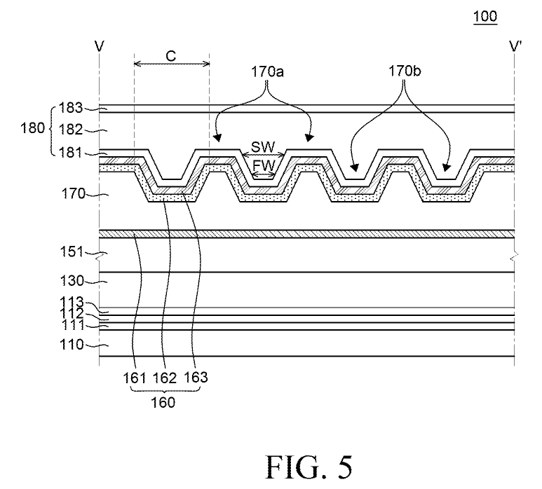

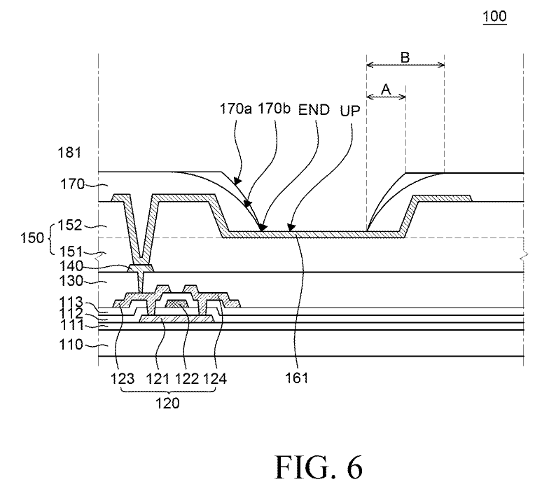

FIG. 1 is a plan view of a display apparatus according to an exemplary embodiment of the present disclosure. FIG. 2 is an enlarged plan view of one sub pixel of a display apparatus according to an exemplary embodiment of the present disclosure. FIG. 3 is a cross-sectional view of a display apparatus taken along III-III′ of FIG. 2. FIG. 4 is a cross-sectional view of a display apparatus taken along IV-IV′ of FIG. 2. FIG. 5 is a cross-sectional view of a display apparatus taken along V-V′ of FIG. 2. FIG. 6 is a cross-sectional view for comparing shapes of a first side surface and a second side surface of a bank of a display apparatus according to an exemplary embodiment of the present disclosure. At this time, FIGS. 3 and 4 are cross-sectional views for a first side surface 170a and a second side surface 170b of a bank 170 of a display apparatus 100 according to an exemplary embodiment of the present disclosure, respectively. In the meantime, in FIG. 6, in order to compare shapes of the first side surface 170a and the second side surface 170b of the bank 170, the first side surface 170a and the second side surface 170b are illustrated to overlap and a configuration above the bank 170 is not illustrated.

Referring to FIGS. 1 to 6, the display apparatus 100 includes a substrate 110, a transistor 120, a first over coating layer 130, an auxiliary electrode 140, a second over coating layer 150, a light emitting diode 160, a bank 170, and an encapsulation unit 180. The display apparatus 100 may be implemented as a top emission type display apparatus, but is not limited thereto.

The substrate 110 is a substrate which supports and protects a plurality of components of the display apparatus 100. The substrate 110 may be formed of a glass or a plastic material having flexibility. When the substrate 110 is formed of a plastic material, for example, the substrate may be formed of polyimide (PI), but it is not limited thereto.

The substrate 110 includes an active area AA and a non-active area NA.

The active area AA is an area in which an image is displayed in the display apparatus 100 and a display element and various driving elements for driving the display element may be disposed in the active area AA. For example, the display element may be configured by a light emitting diode 160 including a first electrode 161, an organic layer 162, and a second electrode 163. Further, various driving elements for driving the display element, such as a transistor 120, a capacitor, or wiring lines may be disposed in the active area AA.

A plurality of sub pixels SP may be included in the active area AA. The sub pixel SP is a minimum unit which configures a screen and each of the plurality of sub pixels SP may include a light emitting diode 160 and a driving circuit. The plurality of sub pixels SP may emit light having different wavelengths. For example, the plurality of sub pixels SP may include a red sub pixel SPR, a green sub pixel SPG, and a blue sub pixel SPB. Further, the plurality of sub pixels SP may further include a white sub pixel.

In the meantime, referring to FIG. 2, the plurality of sub pixels SP included in one sub pixel may be disposed with different areas. For example, in one column, a blue sub pixel SPB is disposed and in an adjacent column, a red sub pixel SPR and a green sub pixel SPG are disposed together. Further, the red sub pixel SPR and the green sub pixel SPG may be alternately disposed in the same column. However, the red sub pixel SPR, the green sub pixel SPG, and the blue sub pixel SPB are disposed in different columns with the same area and a placement, the number, and a color combination of the plurality of sub pixels SP may vary in various forms depending on the design, but are not limited thereto.

The driving circuit of the sub pixel SP is a circuit for controlling the driving of the light emitting diode 160. For example, the driving circuit may be configured to include the transistor 120 and the capacitor, but is not limited thereto.

The non-active area NA is an area where no image is displayed and various components for driving the plurality of sub pixels SP disposed in the active area AA may be disposed in the non-active area NA. For example, a driving IC which supplies a signal for driving the plurality of sub pixels SP and a flexible film may be disposed.

The non-active area NA may be an area which encloses the active area AA as illustrated in FIG. 1, but is not limited thereto. For example, the non-active area NA may be an area extending from the active area AA.

Hereinafter, the plurality of sub pixels SP disposed in the active area AA will be described in more detail with reference to FIGS. 3 to 6.

Referring to FIGS. 3 to 6, a buffer layer 111 is disposed on the substrate 110. The buffer layer 111 may improve adhesive strength between layers formed on the buffer layer 111 and the substrate 110 and block alkali components leaked from the substrate 110. The buffer layer 111 may be formed of a single layer of silicon nitride (SiNx) or silicon oxide (SiOx) or a multiple layer of silicon nitride (SiNx) and silicon oxide (SiOx), but is not limited thereto. The buffer layer 111 may be omitted based on a type or a material of the substrate 110 and a structure and a type of the thin film transistor 120.

The buffer layer 111 is disposed on the substrate 110. The buffer layer 111 may serve to improve adhesive strength between layers formed on the buffer layer 111 and the substrate 110 and block alkali components leaked from the substrate 110. The buffer layer 111 may be formed as a single layer of silicon nitride (SiNx) or silicon oxide (SiOx) or a multiple layer of silicon nitride (SiNx) and silicon oxide (SiOx), but is not limited thereto. The buffer layer 111 is not an essential component and may be omitted based on a type or a material of the substrate 110 and a structure and a type of the transistor 120.

The transistor 120 is disposed on the buffer layer 111. The transistor 120 may be used as a driving element which drives the light emitting diode 160 of the active area AA. The transistor 120 includes an active layer 121, a gate electrode 122, a source electrode 123, and a drain electrode 124. The transistor 120 illustrated in FIGS. 3 and 4 is a driving transistor and is a top gate type thin film transistor in which the gate electrode 122 is disposed on the active layer 121. However, it is not limited thereto and the transistor 120 may be implemented as a bottom gate type transistor.

The active layer 121 is disposed on the buffer layer 111. The active layer 121 is an area in which a channel is formed when the transistor 120 is driven. The active layer 121 may be formed of an oxide semiconductor or amorphous silicon (a-Si), polycrystalline silicon (poly-Si), or an organic semiconductor.

The gate insulating layer 112 is disposed on the active layer 121. The gate insulating layer 112 is a layer for electrically insulating the gate electrode 122 from the active layer 121 and may be formed of an insulating material. For example, the gate insulating layer 112 may be formed as a single layer of silicon nitride (SiNx) or silicon oxide (SiOx) which is an inorganic material or a multiple layer of silicon nitride (SiNx) or silicon oxide (SiOx), but it is not limited thereto.

In the gate insulating layer 112, a contact hole through which the source electrode 123 and the drain electrode 124 are in contact with a source region and a drain region of the active layer 121, respectively, is formed. The gate insulating layer 112 may be formed on the entire surface of the substrate 110 as illustrated in FIGS. 3 to 6, or patterned to have the same width as the gate electrode 122, but is not limited thereto.

The gate electrode 122 is disposed on the gate insulating layer 112. The gate electrode 122 is disposed on the gate insulating layer 112 so as to overlap a channel region of the active layer 121. The gate electrode 122 may be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a multiple layer thereof, but it is not limited thereto.

The interlayer insulating layer 113 is disposed on the gate electrode 122. The interlayer insulating layer 113 may be formed as a single layer of silicon nitride (SiNx) or silicon oxide (SiOx) which is an inorganic material or a multiple layer of silicon nitride (SiNx) or silicon oxide (SiOx), but it is not limited thereto. In the interlayer insulating layer 113, a contact hole through which the source electrode 123 and the drain electrode 124 are in contact with the source region and the drain region of the active layer 121, respectively, is formed.

The source electrode 123 and the drain electrode 124 are disposed on the interlayer insulating layer 113. The source electrode 123 and the drain electrode 124 are disposed on the same layer to be spaced apart from each other. The source electrode 123 and the drain electrode 124 are electrically connected to the active layer 121 through the contact holes of the gate insulating layer 112 and the interlayer insulating layer 113. The source electrode 123 and the drain electrode 124 may be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a multiple layer thereof, but the present disclosure is not limited thereto.

In FIGS. 3 and 4, only a driving transistor, among various transistors 120 included in the display apparatus 100, is illustrated, but other transistors such as a switching transistor may also be disposed.

The first over coating layer 130 is disposed on the interlayer insulating layer 113 and the transistor 120. The first over coating layer 130 is an insulating layer which protects the transistor 120 and planarizes an upper portion of the transistor 120. A contact hole which exposes the source electrode 123 of the transistor 120 is formed on the first over coating layer 130. Even though in FIGS. 3 and 4, it is illustrated that a contact hole which exposes the source electrode 123 is formed on the first over coating layer 130, but it is not limited thereto. For example, a contact hole which exposes the drain electrode 124 may be formed on the first over coating layer 130.

The first over coating layer 130 may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

In the meantime, a passivation layer which covers the interlayer insulating layer 113 and the transistor 120 may be further disposed below the first over coating layer 130. The passivation layer may be formed as a single layer of silicon nitride (SiNx) or silicon oxide (SiOx) or a multiple layer of silicon nitride (SiNx) or silicon oxide (SiOx), but it is not limited thereto.

The auxiliary electrode 140 is disposed on the first over coating layer 130. The auxiliary electrode 140 may serve to electrically connect the transistor 120 and the light emitting diode 160. The auxiliary electrode 140 is electrically connected to the source electrode 123 of the transistor 120 through a contact hole formed in the first over coating layer 130. The auxiliary electrode 140 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second over coating layer 150 is disposed on the first over coating layer 130. The second over coating layer 150 is an insulating layer for planarizing upper portions of the first over coating layer 130 and the auxiliary electrode 140. A contact hole which exposes the auxiliary electrode 140 is formed on the second over coating layer 150.

The second over coating layer 150 may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The second over coating layer 150 includes a base portion 151 and a plurality of protrusions 152. As illustrated in FIGS. 3 to 6, the base portion 151 and the plurality of protrusions 152 may be integrally formed. For example, the base portion 151 and the plurality of protrusions 152 are formed of the same material to be simultaneously formed by the same process, for example, by a mask process, but are not limited thereto.

The base portion 151 is disposed on the first over coating layer 130. A top surface of the base portion 151 has a surface parallel to the substrate 110. Therefore, a step generated due to components disposed therebelow may be planarized by the base portion 151.

The plurality of protrusions 152 is disposed on the base portion 151. The plurality of protrusions 152 is integrally formed with the base portion 151 to protrude from the base portion 151. Top surfaces of the plurality of protrusions 152 may be smaller than bottom surfaces, but are not limited thereto.

Each of the plurality of protrusions 152 includes a top surface and a side surface. The top surface of the protrusion 152 is a surface located on an uppermost portion of the protrusion 152 and may be a surface substantially parallel to the base portion 151 or the substrate 110. The side surface of the protrusion 152 may be a surface which connects the top surface of the protrusion 152 and the base portion 151. The side surface of the protrusion 152 may be inclined from the top surface toward the base portion 151, but is not limited thereto.

The light emitting diode 160 is disposed on the second over coating layer 150. The light emitting diode 160 includes a first electrode 161 which is electrically connected to the source electrode 123 of the transistor 120, an organic layer 162 disposed on the first electrode 161, and a second electrode 163 formed on the organic layer 162.

The first electrode 161 is disposed so as to correspond to each of the plurality of sub pixels SP. The first electrode 161 is disposed so as to cover the base portion 151 and the plurality of protrusions 152. The first electrode 161 may be disposed along a shape of the base portion 151 and the plurality of protrusions 152 of the second over coating layer 150. Specifically, the first electrode 161 may be disposed on the top surface of the base portion 151 in which the protrusion 152 is not disposed and side surfaces of the plurality of protrusions 152. That is, the first electrode 161 is disposed along the shape of the base portion 151 and the protrusions 152. Further, the first electrode 161 may be formed in a partial area of the top surface of the plurality of protrusions 152.

The first electrode 161 may be an anode of the light emitting diode 160. The first electrode 161 is electrically connected to the auxiliary electrode 140 through the contact hole which is formed on the second over coating layer 150. The first electrode 161 may be electrically connected to the source electrode 123 of the transistor 120 through the auxiliary electrode 140. However, the first electrode 161 may be configured to be electrically connected to the drain electrode 124 of the transistor 120 depending on a type of the transistor 120 and a design manner of the driving circuit.

At this time, even though in FIGS. 3 to 6, the first electrode 161 is illustrated as a single layer, the first electrode 161 may be configured as a multi-layer. For example, the first electrode 161 may include a reflective layer which reflects light emitted from the organic layer 162 toward the second electrode 163 and a transparent conductive layer which supplies holes to the organic layer 162.

The reflective layer is disposed on the second over coating layer 150 to reflect light emitted from the light emitting diode 160 upwardly. The light generated in the organic layer 162 of the light emitting diode 160 may be emitted not only upwardly, but also laterally. The light which is laterally emitted is directed to the inside of the display apparatus 100 or trapped in the display apparatus 100 due to the total reflection, or further travels to the inside of the display apparatus 100 and then disappears. Therefore, the reflective layer is disposed below the organic layer 162 to cover side portions of the plurality of protrusions 152 to change a traveling direction of the light which is directed to a side portion of the organic layer 162 to a front direction.

The reflective layer may be formed of a metal material, for example, such as aluminum (Al), silver (Ag), copper (Cu), and a magnesium-silver alloy (Mg:Ag), but is not limited thereto.

The transparent conductive layer is disposed on the reflective layer. The transparent conductive layer may be formed of a conductive material having a high work function to supply holes to the organic layer 162. For example, the transparent conductive layer may be formed of transparent conductive oxide such as indium tin oxide (ITO), indium zinc oxide (IZO), indium tin zinc oxide (ITZO), zinc oxide (ZnO), and tin oxide (TO), but is not limited thereto.

The bank 170 is disposed on the second over coating layer 150 and the first electrode 161. The bank 170 is disposed on the protrusion 152 of the second over coating layer 150 and a part of the first electrode 161 and has an inclined side surface. For example, as illustrated in FIGS. 3 and 4, a top surface of the bank 170 is a flat surface and a side surface of the bank 170 may be an inclined surface. At this time, the side surface of the bank 170 may be defined from a top surface of the bank 170 which is a flat surface to an end of the bank 170 through which the first electrode 161 is exposed, i.e., is not covered, but is not limited thereto.

The bank 170 is an insulating layer which separates adjacent sub pixels SP. In the bank 170, an open area which exposes an uncovered part UP of the first electrode 161 may be disposed and in the bank 170, a non-open area which covers a part of the first electrode 161 is disposed to define the emission area and the non-emission area.

The emission area refers to an area in which light is directly generated by the organic layer 162 in each of the plurality of sub pixels SP. The emission area is an opening area of the bank 170 so that the bank 170 is not disposed and the organic layer 162 is disposed directly on the first electrode 161 to generate light.

The non-emission area may refer to an area in which the light is not directly generated. The non-emission area is a non-opening area of the bank 170 so that the bank 170 is disposed between the first electrode 161 and the organic layer 162 to block direct generation of light.

The non-emission area may include a reflection area RA. Here, the reflection area RA is an area corresponding to a side surface of the bank 170 in which the first electrode 161 is disposed. In the reflection area RA, the reflective layer of the first electrode 161 formed on the side portion of the protrusion 152 serves as a side mirror so that some of light which may be trapped in the display apparatus 100 by the total reflection is extracted to the outside of the display apparatus 100.

The bank 170 may be formed of an inorganic material. For example, the bank 170 may be formed of a single layer of silicon nitride (SiNx) or silicon oxide (SiOx) or a multiple layer of silicon nitride (SiNx) and silicon oxide (SiOx). However, it is not limited thereto and the bank 170 may be formed of an organic material.

Referring to FIGS. 2 to 6, the bank 170 includes a plurality of first side surfaces 170a and a plurality of second side surfaces 170b. The plurality of first side surfaces 170a and the plurality of second side surfaces 170b have different average inclination angles from the side surface of the bank 170. Therefore, in the bank 170, a plurality of trenches defined by the side surfaces and which are created by way of partially removing the side surfaces may be disposed by the difference in the average inclination angles of the plurality of first side surfaces 170a and the plurality of second side surfaces 170b. For example, the second side surface 170b may be a trench obtained by partially removing the first side surface 170a. That is, the first side surface 170a is a part of the side surface of the bank 170 in which the plurality of trenches is not disposed and the second side surface 170b may be a part of the side surface of the bank 170 in which the plurality of trenches is disposed. By way of the removal of the trench from side surface of the bank 170, the second side surface 170b is adjacent to the first side surface 170a.

For example, the second side surface 170b may be formed by a method of removing the bank 170 in a part corresponding to the second side surface 170b, not completely, but reducing only the thickness, using a mask in which a slit is formed in a part corresponding to the second side surface 170b during a patterning process of placing a material for forming the bank 170 on the first electrode 161 and partially removing the material for forming the bank 170, but is not limited thereto.

Referring to FIGS. 2 and 5, on the side surface of the bank 170, a plurality of first side surfaces 170a and a plurality of second side surfaces 170b may be alternately disposed. The plurality of first side surfaces 170a and the plurality of second side surfaces 170b may be alternately disposed along an end of the bank 170 which exposes the first electrode 161. The end of the bank 170 on a respective first side surface 170a may be colinear with the end of the bank 170 on a respective second side surface 170b when the respective first side surface 170a is adjacent to the respective second side surface 170b.

For example, as illustrated in FIG. 2, if a planar shape formed by the end of the bank 170 which exposes the first electrode 161 is a polygonal shape, the plurality of second side surfaces 170b may be disposed on sides of the polygon. Further, the plurality of first side surfaces 170a may be disposed between vertices of the polygon and the plurality of second side surfaces 170b, respectively.

In the meantime, as illustrated in FIG. 2, the plurality of first side surfaces 170a and the plurality of second side surfaces 170b may each present on each sub pixel. If the plurality of sub pixels SP has different areas, in each of the sub pixels SP, the number of the plurality of first side surfaces 170a and the number of second side surfaces 170b are different. That is, the number of the plurality of second side surfaces 170b may vary according to a type and an area of the planar shape formed by the end of the bank 170. For example, the larger the area of the planar shape formed by the end of the bank 170, the larger the number of the plurality of first side surfaces 170a and the plurality of second side surfaces 170b included in the bank 170.

Referring to FIG. 3, in the first side surface 170a, an inclination formed by the top surface of the base portion 151 is increased from the top surface of the bank 170 to the end of the bank 170. However, the first side surface 170a may be disposed so as to form a predetermined inclination angle with the top surface of the base portion 151, but is not limited thereto. At this time, an average inclination angle formed by the first side surface 170a and the top surface of the base portion 151 may be, for example, 55° to 65°, but is not limited thereto.

Referring to FIG. 6, an average inclination angle of the second side surface 170b may be smaller than that of the first side surface 170a. That is, the average inclination angle formed by the second side surface 170b and the top surface of the base portion 151 may be smaller than the average inclination angle formed by the first side surface 170a and the top surface of the base

portion 151. For example, an average inclination angle formed by the second side surface 170b and the top surface of the base portion 151 may be, for example, 35° to 45°, but is not limited thereto.

In the meantime, referring to FIG. 4, in the second side surface 170b, an inclination formed by the top surface of the base portion 151 is increased from the top surface of the bank 170 to the end of the bank 170. However, the second side surface 170b may be disposed so as to form a predetermined inclination angle with the top surface of the base portion 151, but is not limited thereto.

In the meantime, referring to FIG. 5, the second side surface 170b between the plurality of first side surfaces 170a has a width which downwardly reduces. For example, each second side surface 170b, as illustrated in FIG. 5, may have a trench shape formed by two inclined side surfaces and a bottom surface in an area between the plurality of first side surfaces 170a, but is not limited thereto. In such an example, the second side surface 170b has a first width FW smaller than a second width SW of the second side surface 170b, and the second width SW is further from the substrate 110 than the first width FW.

Referring to FIGS. 2 and 6, a second length B from a flat surface of the bank 170 to an end of the bank 170 on the second side surface 170b in a dimension parallel to the substrate 110 may be larger than a first length A from the flat surface of the bank 170 to the end of the bank 170 on the first side surface 170a in a dimension parallel to the substrate 110. That is, on the second side surface 170b, an inclined surface larger than that of the first side surface 170a may be disposed.

Referring to FIGS. 2 and 5, on the second side surface 170b, a second length B from a flat surface of the bank 170 to an end of the bank 170 may be larger than a third length C between one first side surface 170a and the other first side surface 170a adjacent thereto. That is, the second length B from the flat surface of the bank 170 to the end on the second side surface 170b may be larger than the third length C which is a width of the second side surface 170b.

The organic layer 162 is disposed on the first electrode 161 and the bank 170. For example, the organic layer 162 is disposed on the first electrode 161 in the emission area and is disposed on the bank 170 in the non-emission area. The organic layer 162 may be disposed along the shapes of the first electrode 161 and the bank 170. The organic layer 162 includes an emission layer and a common layer.

The emission layer is an organic layer which emits light with a specific color. Different emission layers may be disposed in the plurality of sub pixels SP or the same emission layer may be disposed in all the plurality of sub pixels SP. For example, when different emission layers are disposed in the plurality of sub pixels SP, a red emission layer is disposed in a red sub pixel SPR, a green emission layer is disposed in the green sub pixel SPG, and a blue emission layer may be disposed in the blue sub pixel SPB. When the same emission layer is disposed in all the plurality of sub pixels SP, light from the emission layer may be converted to various color light through a separate light conversion layer and a color filter.

The common layer is an organic layer which is disposed to improve luminous efficiency of the emission layer. The common layer may be formed as the same layer over the plurality of sub pixels SP. That is, the common layers of the plurality of sub pixels SP may be simultaneously formed with the same material by the same process. The common layer may include a hole injection layer, a hole transport layer, an electron transport layer, an electron injection layer, and a charge generation layer, but is not limited thereto.

The second electrode 163 is disposed on the organic layer 162. The second electrode 163 may be disposed along the shape of the organic layer 162. The second electrode 163 supplies electrons to the organic layer 162 so that the second electrode may be formed of a conductive material having a low work function. The second electrode 163 may be a cathode of the light emitting diode 160. The second electrode 163 may be formed of a transparent conductive material such as indium tin oxide (ITO) or indium zinc oxide (IZO), or a metal alloy such as MgAg or a ytterbium (Yb) alloy and may further include a metal doping layer, but is not limited thereto. In the meantime, even though it is not illustrated in the drawing, the second electrode 163 is electrically connected to a low potential power line to be supplied with a low potential power signal.

An encapsulation unit 180 may be formed on the light emitting diode 160 to protect the light emitting diode 160 which is vulnerable to moisture so as not to be exposed to the moisture. The encapsulation unit 180 may block the oxygen and moisture which permeates into the display apparatus 100 from the outside. For example, when display apparatus 100 is exposed to the moisture or oxygen, a pixel shrink phenomenon that the emission area is shrunk occurs or a dead pixel in the emission area is generated. Therefore, the encapsulation unit 180 blocks the oxygen and moisture to protect the display apparatus 100. For example, the encapsulation unit 180 may have a structure in which inorganic layers and organic layers are alternately laminated, but is not limited thereto.

Referring to FIGS. 3 to 5, the encapsulation unit 180 includes a first inorganic encapsulation layer 181, an organic encapsulation layer 182, and a second inorganic encapsulation layer 183.

The first inorganic encapsulation layer 181 is disposed on the second electrode 163 to suppress the permeation of the moisture or oxygen. The first inorganic encapsulation layer 181 may be formed of an inorganic material such as silicon nitride (SiNx), silicon oxy nitride (SiNxOy), or aluminum oxide (AlyOz), but is not limited thereto.

The organic encapsulation layer 182 is disposed on the first inorganic encapsulation layer 181 to planarize the surface. Further, the organic encapsulation layer 182 may cover foreign materials or particles which may be generated during a manufacturing process. The organic encapsulation layer 182 is formed of an organic material, for example, polyimide, polycarbonate, acryl, or epoxy based resin, but is not limited thereto. In the meantime, referring to FIG. 5, the first inorganic encapsulation layer 181 and the organic encapsulation layer 182 may be disposed in a space formed by the second side surfaces 170b of the bank 170. That is, the first inorganic encapsulation layer 181 and the organic encapsulation layer 182 may be filled in a space formed by the second side surfaces 170b.

The second inorganic encapsulation layer 183 is disposed on the organic encapsulation layer 182 and may suppress the permeation of the moisture or oxygen, like the first inorganic encapsulation layer 181. The second inorganic encapsulation layer 183 may be formed of an inorganic material such as silicon nitride (SiNx), silicon oxynitride (SiNxOy), silicon oxide (SiOx), or aluminum oxide (AlyOz), but is not limited thereto. The second inorganic encapsulation layer 183 may be formed of the same material as the first inorganic encapsulation layer 181 or formed of a different material.

In the meantime, each of the plurality of sub pixels SP includes an emission area and a non-emission area. For example, the emission area includes a first emission area and a second emission area and the non-emission area includes a first non-emission area and a second non-emission area. For example, the first emission area, the first non-emission area, the second emission area, and the second non-emission area may be defined by the bank 170.

The first emission area corresponds to an area in which the first electrode 161 is exposed from the bank 170, in other words, the uncovered part UP of the first electrode 161. The first emission area may refer to an area in which light is substantially generated by the organic layer 162 in each of the plurality of sub pixels SP. In the first emission area, the bank 170 is not disposed and the organic layer 162 is located directly on the first electrode 161 to generate light.

The first non-emission area encloses the first emission area and corresponds to an area where the bank 170 is disposed on the first electrode 161 on the base portion 151. At this time, the first non-emission area corresponds to an area which does not overlap the side surface of the protrusion 152. When the display apparatus 100 is on, the first non-emission area is in a black state or has a luminance lower than those of the first emission area and the second emission area due to light incident from at least one of the first emission area and the second emission area.

The second emission area encloses the first non-emission area and corresponds to the side surface of the protrusion 152. The second emission area may be an area in which some of light emitted from the organic layer 162 is reflected by the first electrode 161 disposed on the inclined side surface of the protrusion 152 (i.e., the reflection area RA) to be extracted to the outside of the display apparatus 100. Each of the first side surface 170a and the second side surface 170b may be between the reflection area RA of the first electrode 161 and the uncovered part UP of the first electrode 161. Further, the luminance of the second emission area is lower than the luminance of the first emission area, but is not limited thereto.

The second non-emission area encloses the second emission area and corresponds to the flat top surface of the protrusion 152. The second non-emission area may be an area in which various components for driving the emission area are disposed.

When the display apparatus 100 is on, the second non-emission area is in a black state or has a luminance lower than those of the first emission area and the second emission area due to light incident from at least one of the first emission area and the second emission area. Further, when the luminance of the second non-emission area is lower than the luminance of the first emission area and the second emission area, the luminance of the first non-emission area may be higher than the luminance of the second non-emission area, but is not limited thereto.

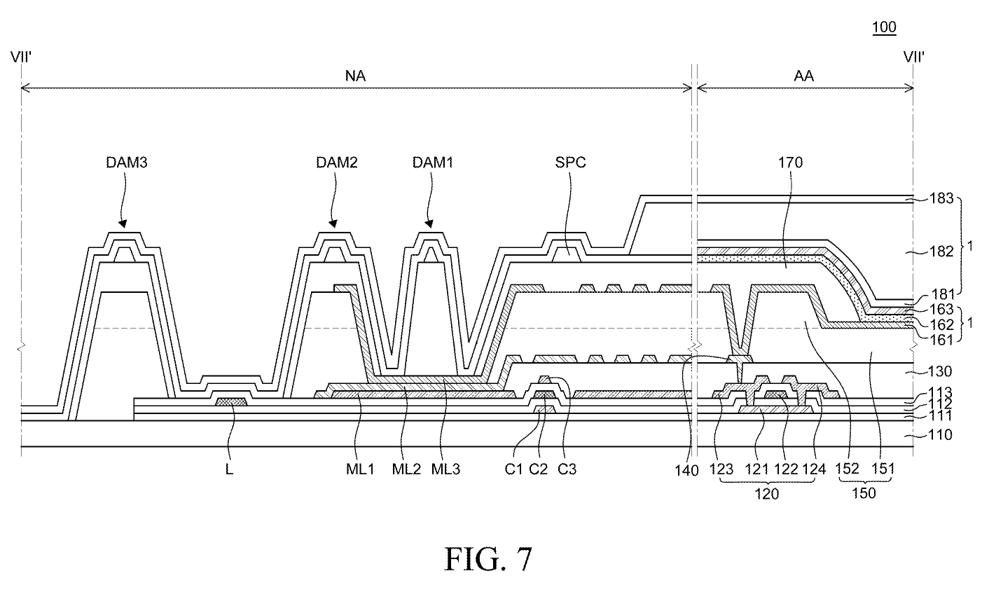

FIG. 7 is a cross-sectional view of a display apparatus taken along VII-VII′ of FIG. 1. FIG. 7 is a cross-sectional view of a non-active area NA of a display apparatus 100 according to an exemplary embodiment of the present disclosure.

Referring to FIG. 7, in the non-active area NA which encloses the active area AA, a spacer SPC, a first dam DAM1, a second dam DAM2, a third dam DAM3, a first metal layer ML1, a second metal layer ML2, a third metal layer ML3, a first conductive layer C1, a second conductive layer C2, a third conductive layer C3, and a wiring line L are disposed.

The spacer SPC is disposed above the bank 170 in the non-active area NA. The spacer SPC serves to maintain a predetermined gap so that the mask is not in contact with the substrate during a manufacturing process of the organic layer 162 formed of an organic material.

The spacer SPC may be disposed so as to enclose all the outer periphery of the active area AA in the non-active area NA. For example, the spacer SPC is disposed to enclose all the outer periphery of the active area AA while forming a closed loop shape to block the flow of the organic encapsulation layer 182. Therefore, the spacer SPC may be referred to as a top stopper, for example, but is not limited thereto.

In the meantime, even though in the drawing, it is illustrated that the spacer SPC is disposed only in the non-active area NA, the spacer SPC may also be disposed above the bank 170 corresponding to an area between the plurality of sub pixels SP in the active area AA. At this time, the organic layer 162 and the second electrode 163 may be disposed on the spacer SPC disposed above the bank 170 in the active area AA, but is not limited thereto.

For example, the spacer SPC may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

In the non-active area NA, a plurality of dams is disposed at the outside of the spacer SPC. The plurality of dams may include a first dam DAM1, a second dam DAM2, and a third dam DAM3. The first dam DAM1, the second dam DAM2, and the third dam DAM3 may be disposed so as to enclose all the outer periphery of the active area AA in the non-active area NA. For example, the first dam DAM1, the second dam DAM2, and the third dam DAM3 may be disposed so as to enclose all the outer periphery of the active area AA while forming a closed loop shape. The first dam DAM1, the second dam DAM2, and the third dam DAM3 may be configured to block the flow of the components formed of an organic material, for example, such as the organic encapsulation layer 182 in the non-active area NA, but is not limited thereto.

The first dam DAM1 is disposed between the second dam DAM2 and the spacer SPC. For example, the first dam DAM1 may be formed of the same material as the bank 170 and the spacer SPC, but is not limited thereto. For example, the first dam DAM1 may be referred to as a mid stopper, but is not limited thereto.

The second dam DAM2 is disposed at the outside of the first dam DAM1. For example, the second dam DAM2 may be formed of the same material as the second over coating layer 150, the bank 170, and the spacer SPC, but is not limited thereto.

The third dam DAM3 is disposed at the outside of the second dam DAM2. For example, the third dam DAM3 may be formed of the same material as the second over coating layer 150, the bank 170, and the spacer SPC, but is not limited thereto. In the meantime, the third dam DAM3 may be disposed so as to cover ends of the inorganic insulating layers extending from the active area AA to the non-active area NA. Therefore, the third dam DAM3 may minimize the propagation of the cracks to the inorganic insulating layers by protecting the ends of the inorganic insulating layers, but is not limited thereto.

Referring to FIG. 7, in the non-active area NA, a first metal layer ML1, a second metal layer ML2, and a third metal layer ML3 are disposed.

The first metal layer ML1 may be disposed on the interlayer insulating layer 113 in the non-active area NA. The first metal layer ML1 may be, for example, a low potential power line for transmitting a low potential power voltage to the second electrode 163, but is not limited thereto.

The first metal layer ML1 may be disposed on the same layer as the source electrode 123 and the drain electrode 124 on the interlayer insulating layer 113. For example, the first metal layer ML1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The second metal layer ML2 may be disposed on the first metal layer ML1 and the first over coating layer 130 in the non-active area NA. The second metal layer ML2 is disposed on the top surface of the first metal layer ML1 which is exposed from the first over coating layer 130 to be electrically connected to the first metal layer ML1.

The second metal layer ML2 is disposed on the same layer as the auxiliary electrode 140 and is formed of the same material as the auxiliary electrode 140. The second metal layer ML2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The third metal layer ML3 may be disposed on the second metal layer ML2 and the second over coating layer 150 in the non-active area NA. The third metal layer ML3 is disposed on the second metal layer ML2 which is exposed from the second over coating layer 150 to be electrically connected to the second metal layer ML2.

The third metal layer ML3 is disposed on the same layer as the first electrode 161 and is formed of the same material as the first electrode 161. However, the third metal layer ML3 is spaced apart from the first electrode 161 and is not electrically connected thereto and may serve as a separate configuration. For example, the third metal layer ML3 may be formed as a single layer or multiple layers including a metallic material, but is not limited thereto.

In the meantime, even though it is not illustrated in the drawing, the third metal layer ML3 may be electrically connected to the second electrode 163. For example, the bank 170 is disposed on the third metal layer ML3 and the second electrode 163 may be electrically connected to the third metal layer ML3 through a contact hole formed in the bank 170, but is not limited thereto. Therefore, the first metal layer ML1 may be electrically connected to the second electrode 163 through the second metal layer ML2 and the third metal layer ML3 and may transmit the low potential power voltage to the second electrode 163.

In the meantime, referring to FIG. 7, in the non-active area NA, a plurality of conductive layers may be disposed. For example, the plurality of conductive layers may include a first conductive layer C1, a second conductive layer C2, and a third conductive layer C3. For example, each of the first conductive layer C1, the second conductive layer C2, and the third conductive layer C3 is disposed between a plurality of inorganic insulating layers to minimize propagation of cracks of the plurality of inorganic insulating layers, but is not limited thereto.

In the meantime, a wiring line L may be disposed between the second dam DAM2 and the third dam DAM3. The wiring line L may be disposed so as to enclose an outer periphery of the active area AA in the non-active area NA. For example, the wiring line L is a configuration for sensing a crack of the display apparatus 100 in the non-active area NA and is formed of the same material as the gate electrode 122 disposed in the active area AA and a plurality of wiring lines L may also be disposed, but is not limited thereto.

The display apparatus in which a side surface of an anode is disposed on an inclined surface to be used as a reflection surface is advantageous in that light emitted from the light emitting diode is reflected from the inclined side surface of the anode to improve the light extraction efficiency. However, as the anode is disposed on the inclined surface, a step may occur between a center portion and a peripheral portion of the light emitting diode and a non-application defect that the organic encapsulation layer of the encapsulation unit disposed above the light emitting diode does not fully fill the center portion of the light emitting diode is caused due to the step. Accordingly, the encapsulation unit which blocks oxygen and moisture which permeates into the display apparatus and planarizes an upper portion of the plurality of light emitting diodes is damaged to degrade the reliability and the aesthetics of the display apparatus.

Accordingly, in the display apparatus 100 according to the exemplary embodiment of the present disclosure, the bank 170 includes a plurality of first side surfaces 170a and a plurality of second side surfaces 170b. Therefore, the non-application defect that the organic encapsulation layer 182 does not fully fill the upper portion of the light emitting diode 160 may be minimized.

Specifically, in the display apparatus 100 according to the exemplary embodiment of the present disclosure, the bank 170 includes a plurality of first side surfaces 170a and a plurality of second side surfaces 170b each having different average inclination angles. The plurality of second side surfaces 170b may define a trench formed by partially removing the first side surface 170a and has a smaller average inclination angle than that of the first side surface 170a. A second length B from a flat surface of the bank 170 to an end of the bank 170 on the second side surface 170b may be larger than a first length A from the flat surface of the bank 170 to the end of the bank 170 on the first side surface 170a. Further, a second length B from a flat surface of the bank 170 to an end of the bank 170 on the second side surface 170b may be larger than a third length C between one first side surface 170a and the other first side surface 170a adjacent thereto. That is, the second side surface 170b may form a trench which is narrow and long. At this time, by the capillary phenomenon of the narrow and long trench, the organic encapsulation layer 182 disposed above the light emitting diode 160 may be induced to move from the peripheral portion of the light emitting diode 160 corresponding to the flat surface of the bank 170 to the center portion of the light emitting diode 160. Accordingly, in the display apparatus 100 according to the exemplary embodiment of the present disclosure, the bank 170 includes a plurality of first side surfaces 170a and a plurality of second side surfaces 170b. Therefore, the non-application defect that the organic encapsulation layer 182 does not fully fill the upper portion of the light emitting diode 160 may be minimized and the reliability and the aesthetics of the display apparatus 100 may be improved.

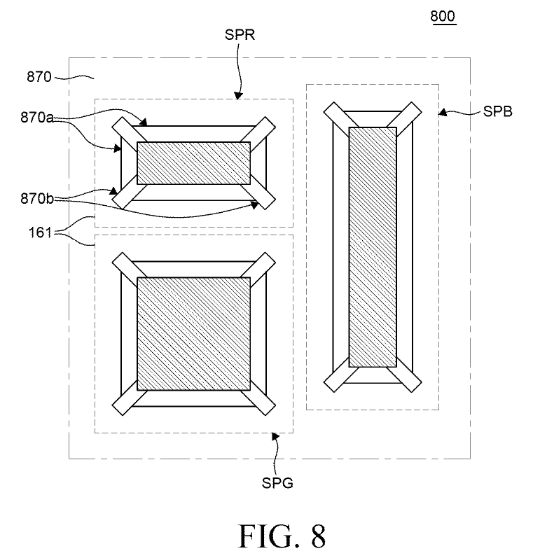

FIG. 8 is an enlarged plan view of one sub pixel of a display apparatus according to another exemplary embodiment of the present disclosure. The only difference between a display apparatus 800 of FIG. 8 and the display apparatus 100 of FIGS. 1 to 7 is a position in which a plurality of first side surfaces 870a and a plurality of second side surfaces 870b are disposed, but the other configurations are substantially the same, so that a redundant description will be omitted.

Referring to FIG. 8, if a planar shape formed by ends of a bank 870 which exposes the first electrode 161 is a polygonal shape, the plurality of second side surfaces 870b may be disposed on vertices of the polygon. Further, the plurality of first side surfaces 870a may be disposed between the plurality of second side surfaces 870b corresponding to sides of the polygon. For example, when one sub pixel SP has a small diameter of approximately 20 μm or smaller, even though the second side surface 870b is disposed only on the vertices of the polygonal shape formed by the ends of the bank 870, the organic encapsulation layer 182 may be filled in a space formed by the second side surface 870b. However, the present disclosure is not limited thereto.

In the display apparatus 800 according to another exemplary embodiment of the present disclosure, the bank 870 includes a plurality of first side surfaces 870a and a plurality of second side surfaces 870b. Therefore, the non-application defect that the organic encapsulation layer 182 does not fully fill the upper portion of the light emitting diode 160 may be minimized.

Specifically, in the display apparatus 800 according to another exemplary embodiment of the present disclosure, the bank 870 includes a plurality of first side surfaces 870a and a plurality of second side surfaces 870b each having different average inclination angles. The plurality of second side surfaces 870b may be a trench formed by partially removing the first side surface 870a and has a smaller average inclination angle than that of the first side surface 870a. A second length B from a flat surface of the bank 870 to an end of the bank 870 on the second side surface 870b may be larger than a first length A from the flat surface of the bank 870 to the end of the bank 870 on the first side surface 870a. Further, a second length B from a flat surface of the bank 870 to an end of the bank 870 on the second side surface 870b may be larger than a third length C between one first side surface 870a and the other first side surface 870a adjacent thereto. That is, the second side surface 870b may form a trench which is narrow and long. At this time, by the capillary phenomenon of the narrow and long trench, the organic encapsulation layer 182 disposed above the light emitting diode 160 may be induced to move from the peripheral portion of the light emitting diode 160 corresponding to the flat surface of the bank 870 to the center portion of the light emitting diode 160. Accordingly, in the display apparatus 800 according to another exemplary embodiment of the present disclosure, the bank 870 includes a plurality of first side surfaces 870a and a plurality of second side surfaces 870b. Therefore, the non-application defect that the organic encapsulation layer 182 does not fully fill the upper portion of the light emitting diode 160 may be minimized and the reliability and the aesthetics of the display apparatus 800 may be improved.

### The exemplary embodiments of the present disclosure can also be described as follows:

According to an aspect of the present disclosure, a display apparatus includes a substrate including a plurality of sub pixels, an over coating layer which is disposed on the substrate and includes a base portion and a protrusion which protrudes from the base portion and has an inclined side surface, a first electrode which is disposed so as to correspond to each of the plurality of sub pixels and cover the base portion and a part of the protrusion, and a bank which has an inclined side surface on the first electrode and the protrusion and exposes a part of the first electrode.

The bank includes a plurality of first side surfaces and a plurality of second side surfaces having an average inclination angle smaller than that of the first side surfaces.

The plurality of second side surfaces define trenches obtained by partially removing the first side surfaces.

A top surface of the bank may be a flat surface and a side surface of the bank connects the flat surface and an end of the bank which exposes the first electrode and a length from the flat surface of the bank to the end of the bank on the second side surface may be larger than a length from the flat surface of the bank to the end of the bank on the first side surface.

On the second side surface, the length from the flat surface to the end of the bank may be larger than a distance between one first side surface and the other first side surfaces adjacent thereto.

The second side surface may have a width which is downwardly reduced.

The plurality of first side surfaces and the plurality of second side surfaces may be alternately disposed.

A planar shape formed by an end of the bank which exposes the first electrode may be a polygon and the plurality of second side surfaces may be disposed on sides of the polygon.

A planar shape formed by an end of the bank which exposes the first electrode may be a polygon and the plurality of second side surfaces may be disposed on vertices of the polygon.

The display apparatus may further comprise an organic layer disposed on the first electrode and the bank, a second electrode disposed on the organic layer, and an encapsulation unit which is disposed on the second electrode and includes a plurality of inorganic encapsulation layers and an organic encapsulation layer.

The organic encapsulation layer may be configured to be filled in a space formed by the plurality of second side surfaces between the plurality of first side surfaces.

According to another aspect of the present disclosure, a display apparatus includes a substrate, an over coating layer which is disposed on the substrate and includes a base portion and a protrusion which protrudes from the base portion and has an inclined side surface, a plurality of first electrodes disposed to cover the base portion and a part of the protruding portion, and a bank which is disposed so as to expose a part of the plurality of first electrodes on the plurality of first electrodes and the protrusion.

The bank includes a top surface which is a flat surface and a side surface which is an inclined area between the ends which expose and encloses the first electrode and a plurality of trenches may be disposed on a side surface of the bank.

An average inclination angle of the side surface of the bank in an area in which the plurality of trenches is disposed may be smaller than an average inclination angle of the side surface of the bank in an area in which the plurality of trenches is not disposed.

A length from the flat surface of the bank to the end of the bank in the area in which the plurality of trenches is disposed may be larger than a length from the flat surface of the bank to the end of the bank in the area in which the plurality of trenches is not disposed.

A length of each trench from the flat surface to the end of the bank may be larger than a width of each trench.

The trench may have a width which is downwardly reduced.

A planar shape formed by an end of the bank which exposes the first electrode may be a polygon and the plurality of trenches may be disposed on sides of the polygon.

A planar shape formed by an end of the bank which exposes the first electrode may be a polygon and the plurality of trenches may be disposed on vertices of the polygon.

The display apparatus may further comprise an organic layer disposed on the first electrode and the bank, a second electrode disposed on the organic layer; and an encapsulation unit which is disposed on the second electrode and includes a plurality of inorganic encapsulation layers and an organic encapsulation layer.

The organic encapsulation layer may be configured to be filled in the plurality of trenches.

The present disclosure further provides embodiments directed to a method of forming a display apparatus.

In one embodiment, a method of forming a display apparatus includes disposing an over coating layer 150 on a substrate 110, the over coating layer 150 including a base portion 151 and a protrusion 152 protruding from the base portion 151 and having an inclined side surface. The substrate 110 includes a plurality of sub pixels SP, and the over coating layer 150 may be disposed so as to cover at least a portion of the substrate 110 and to define the protrusion 152 relative to the base portion 151. A first electrode 161 is disposed on each of the plurality of sub pixels SP such that the first electrode 161 covers the base portion 151 and at least part of the protrusion 152, as depicted in FIG. 3. A bank 170 having an inclined side surface is then disposed on the first electrode 161 and the protrusion 152 such that at least a portion of the first electrode 161 remains uncovered by the bank 170, as illustrated in FIGS. 3-4 . Thereafter, a portion of the side surface of the bank 170 is removed to form a plurality of trenches, such that the side surface of the bank 170 includes a plurality of first side surfaces 170a and a plurality of second side surfaces 170b, the plurality of second side surfaces 170b having an average inclination angle smaller than that of the plurality of first side surfaces 170a, as shown in FIG. 6.

In certain embodiments, and as illustrated in FIGS. 3-4, the bank 170 includes a top surface TS that is a flat surface, and the side surface of the bank 170 connects the flat surface and an end END of the bank 170 adjacent to the uncovered part UP of the first electrode 161. In such embodiments, the plurality of trenches are formed such that a length measured in a dimension parallel to the substrate 110 from the flat surface of the bank 170 to the end of the bank 170 along the second side surface 170b is greater than a length measured in the same dimension from the flat surface of the bank 170 to the end END of the bank 170 along the first side surface 170a, as illustrated in FIG. 6.

In further embodiments, the plurality of trenches are formed such that the length measured from the flat surface of the bank 170 to the end END of the bank 170 along the second side surface 170b is greater than a distance between one first side surface 170a and another first side surface 170a disposed adjacent thereto, as shown in FIG. 6. In this manner, the relative lengths of the side surfaces and the spacing between adjacent side surfaces may be selectively controlled to achieve desired geometries in the resulting bank structure.

In some embodiments, the plurality of trenches are formed such that the end of the bank 170 along each respective first side surface 170a is colinear with the end of the bank 170 along each respective second side surface 170b, the respective first side surface 170a being adjacent to the respective second side surface 170b. Such colinearity may facilitate uniformity in the planar configuration of the bank 170 when viewed from above the substrate 110, as depicted in FIG. 2.

In additional embodiments, and as shown in FIG. 5, the plurality of trenches are formed such that each second side surface 170b tapers in width, having a first width at a location nearer the substrate 110 that is smaller than a second width at a location farther from the substrate 110. The resulting tapered geometry may promote desirable capillary behavior during deposition of subsequent layers.

In some embodiments, the plurality of trenches are formed such that the plurality of first side surfaces 170a and the plurality of second side surfaces 170b are alternately disposed along the side surface of the bank 170, as illustrated in FIG. 2. Such alternating disposition may be repeated along the perimeter of the bank 170 to provide uniformity in trench distribution.

In another embodiment, removal of the plurality of trenches defines a planar shape at an end of the bank 170 adjacent to the uncovered part of the first electrode 161, the planar shape being a polygon when viewed from above (e.g., in plan view) the substrate 110, as shown in FIG. 2. In one implementation, the plurality of second side surfaces 170b is disposed along the sides of the polygon, whereas in another implementation, the plurality of second side surfaces 170b is disposed at the vertices of the polygon, as depicted in FIG. 8. The side or vertex placement of the second side surfaces 170b may be selected depending on pixel size, shape, or other design considerations.

In certain embodiments, after formation of the plurality of trenches, the method further includes disposing an organic layer 162 on the first electrode 161 and the bank 170, disposing a second electrode 163 on the organic layer 162, and disposing an encapsulation unit 180 on the second electrode 163. As shown in FIG. 5, the encapsulation unit 180 includes a plurality of inorganic encapsulation layers 181, 183 and an organic encapsulation layer 182, the encapsulation unit 180 being positioned such that the organic encapsulation layer 182 extends into spaces defined by the plurality of second side surfaces 170b between the plurality of first side surfaces 170a. The extended configuration of the organic encapsulation layer 182 may provide improved planarization and sealing performance.

Finally, in some embodiments, the plurality of trenches are formed such that each sub pixel SP includes both the plurality of first side surfaces 170a and the plurality of second side surfaces 170b. This arrangement may ensure consistent trench geometry across all sub pixels SP of the display apparatus, thereby improving uniformity and reliability of the device.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

Claims:

1. A display apparatus comprising:
a substrate including a plurality of sub pixels;
an over coating layer which is disposed on the substrate and includes a base portion and a protrusion which protrudes from the base portion and has an inclined side surface;
a first electrode which is disposed on each of the plurality of sub pixels and cover the base portion and a part of the protrusion; and
a bank which has an inclined side surface disposed on the first electrode and the protrusion and which does not cover a part of the first electrode,
wherein the bank includes a plurality of first side surfaces and a plurality of second side surfaces having an average inclination angle smaller than that of the plurality of first side surfaces.

2. The display apparatus according to claim 1, wherein the plurality of second side surfaces defines trenches, each trench being adjacent to a first side surface of the plurality of first side surfaces of the bank.

3. The display apparatus according to claim 1, wherein a top surface of the bank is a flat surface and a side surface of the bank connects the flat surface and an end of the bank adjacent to an uncovered part of the first electrode and a length in a dimension parallel to the substrate from the flat surface of the bank to the end of the bank disposed on each second side surface is larger than a length in the dimension parallel to the substrate from the flat surface of the bank to the end of the bank disposed on each first side surface.

4. The display apparatus according to claim 3, wherein the length from the flat surface to the end of the bank disposed on each second side surface is larger than a distance between one first side surface and the other first side surfaces adjacent thereto.

5. The display apparatus according to claim 1, wherein the plurality of first side surfaces and the plurality of second side surfaces are alternately disposed.

6. The display apparatus according to claim 1, wherein a planar shape formed by an end of the bank adjacent to an uncovered part of the first electrode is a polygon and the plurality of second side surfaces is disposed on sides of the polygon.

7. The display apparatus according to claim 1, further comprising:
an organic layer disposed on the first electrode and the bank;
a second electrode disposed on the organic layer; and
an encapsulation unit which is disposed on the second electrode and includes a plurality of inorganic encapsulation layers and an organic encapsulation layer,
wherein the organic encapsulation layer is configured to extend into a space formed by the plurality of second side surfaces between the plurality of first side surfaces.

8. The display apparatus according to claim 1, wherein the plurality of first side surfaces and the plurality of second side surfaces are between a reflection area of the first electrode and the uncovered part of the first electrode.

9. The display apparatus according to claim 1, wherein the plurality of first side surfaces and the plurality of second side surfaces are each present on each sub pixel.

10. A display apparatus comprising:
a substrate;
an over coating layer which is disposed on the substrate and includes a base portion and a protrusion which protrudes from the base portion and has an inclined side surface;
a plurality of first electrodes disposed to cover the base portion and a part of the protruding portion; and
a bank which is disposed such that the bank does not cover a part of the plurality of first electrodes, the bank disposed on the plurality of first electrodes and the protrusion;
wherein the bank includes a top surface which is a flat surface and a side surface which is an inclined area between an end of the bank adjacent to an uncovered part of the first electrode, the bank including the side surface of each of opposing sides of the uncovered part of the first electrode, and
wherein the side surface of the bank defines a plurality of trenches disposed on at least a portion of the side surface of the bank.

11. The display apparatus according to claim 10, wherein an average inclination angle of the side surface of the bank in an area in which the plurality of trenches is disposed is smaller than an average inclination angle of the side surface of the bank in an area in which the plurality of trenches is not disposed.

12. The display apparatus according to claim 10, wherein a length in a dimension parallel to the substrate from the flat surface of the bank to the end of the bank in the area in which the plurality of trenches is disposed is larger than a length in a dimension parallel to the substrate from the flat surface of the bank to the end of the bank in the area in which the plurality of trenches is not disposed.

13. The display apparatus according to claim 12, wherein the length of each trench from the flat surface to the end of the bank is larger than a width of each trench.

14. The display apparatus according to claim 12, wherein the end of the bank in the area in which the plurality of trenches is disposed is colinear with the end of the bank in the area in which the plurality of trenches is not disposed, the area in which the plurality of trenches is disposed adjacent to the area in which the plurality of trenches is not disposed.

15. The display apparatus according to claim 10, wherein the trench has a first width smaller than a second width of the second side surface, the second width of the second side surface further from the substrate than the first width of the second side surface.

16. The display apparatus according to claim 10, wherein a planar shape formed by an end of the bank adjacent to the uncovered part of the first electrode is a polygon and the plurality of trenches is disposed on sides of the polygon.

17. The display apparatus according to claim 10, wherein a planar shape formed by an end of the bank adjacent to the uncovered part of the first electrode is a polygon and the plurality of trenches is disposed on vertices of the polygon.

18. The display apparatus according to claim 10, further comprising:
an organic layer disposed on the first electrode and the bank;
a second electrode disposed on the organic layer; and
an encapsulation unit which is disposed on the second electrode and includes a plurality of inorganic encapsulation layers and an organic encapsulation layer,
wherein the organic encapsulation layer is configured to extend into the plurality of trenches.

19. The display apparatus according to claim 10, wherein the side surface is between a reflection area of the first electrode and the uncovered part of the first electrode.

20. The display apparatus according to claim 10, wherein the side surface of the bank defines a plurality of trenches disposed on at least a portion of the side surface of the bank of each sub pixel.
